(19) United States
(12) Patent Application Publication
(10) Pub. No.: US 2016/0301028 A1
(43) Pub. Date: Oct. 13, 2016

(54) METHOD FOR MANUFACTURING DISPLAY DEVICE AND DISPLAY DEVICE

(71) Applicant: Japan Display Inc., Tokyo (JP)

(72) Inventors: Yoshinori ISHII, Tokyo (JP); Toshihiro SATO, Tokyo (JP)

(21) Appl. No.: 15/092,921

(22) Filed: Apr. 7, 2016

(30) Foreign Application Priority Data
Apr. 9, 2015 (JP) 2015-079859

(51) Int. Cl. H01L 51/52; H01L 51/56; H01L 27/32

(52) U.S. Cl. CPC H01L 51/5246; H01L 27/3244; H01L 51/56; H01L 2227/323

(57) ABSTRACT

A method for manufacturing a display device includes providing an array substrate, providing a counter substrate to be opposed to the array substrate, applying a seal material on at least one of the array substrate and the counter substrate to seamlessly surround the display region, applying a filling material on a region surrounded by the seal material, and bonding the array substrate and the counter substrate together. In the applying the seal material, the seal material is provided to include a first region and a second region having a sectional area orthogonal to a length direction of disposition smaller than a sectional area of the first region. In the bonding the array substrate and the counter substrate together, the filling material is caused to leak to region between the second region and one of the array substrate and the counter substrate.

### CROSS-REFERENCE TO RELATED APPLICATION

The present application claims priority from Japanese application JP 2015-079859 filed on Apr. 9, 2015, the content of which is hereby incorporated by reference into this application.

### BACKGROUND OF THE INVENTION

1. Field of the Invention

The present invention relates to a method for manufacturing a display device and the display device.

2. Description of the Related Art

In recent years, a display device including a self-luminous object such as an organic light emitting diode (OLED) has been put to practical use. Compared with a liquid crystal display device in the past, display devices such as an organic EL (Electro-luminescent) display device including such an OLED is excellent in visibility and response speed because the self-luminous object is used. Moreover, it is possible to reduce thickness because an auxiliary illumination device such as a backlight is unnecessary.

Japanese Patent No. 4712298B2 mentions that, in manufacturing of an organic EL display, a first seal material is rendered on a second substrate in a line shape having an opening, a second seal material is dripped in a region surrounded by the first seal material, and thereafter a first substrate and the second substrate are bonded together.

### SUMMARY OF THE INVENTION

When an organic EL display device or the like is manufactured, a seal material is provided on an array substrate or a counter substrate to surround a display region, a filling material is dripped in the region surrounded by the seal material, and the array substrate and the counter substrate are bonded together. Then, in the region surrounded by the seal material, a phenomenon occurs in which the film thickness of the filling material is different in the vicinity of the seal material and other places. Therefore, for example, if an image is displayed by the organic EL display device, frame-like unevenness occurs in the display region. On the other hand, a frame region surrounding the display region is narrow. If the seal material is divided, the filling material leaked from a region between the divided seal materials causes a problem.

The present invention has been devised in view of the problems and it is an object of the present invention to provide a technique for reducing a difference in film thickness due to a place of a filling material in a region surrounded by a seal material.

Among inventions disclosed in this application, an overview of a representative invention is briefly explained below.

A method for manufacturing a display device according to the present invention includes: providing an array substrate on which a display region for an image is provided; providing a counter substrate to be used and opposed to the array substrate so as to include a region opposed to the display region; applying a seal material on at least one of the array substrate and the counter substrate to seamlessly surround the display region or the region opposed to the display region; applying a filling material on a region surrounded by the seal material; and bonding the array substrate and the counter substrate together via the seal material and the filling material so as to be opposed to each other. In the applying the seal material, the seal material is provided to include a first region and a second region having a sectional area smaller than a sectional area of the first region in which the sectional area is orthogonal to a length direction of disposition. In the bonding the array substrate and the counter substrate together, the filling material is caused to leak to region between the second region of the seal material and at least one of the array substrate and the counter substrate.

According to the present invention, it is possible to reduce a difference in thickness of the filling material due to a place in the region surrounded by the seal material.

### BRIEF DESCRIPTION OF THE DRAWINGS

FIG. 1 is a perspective view schematically showing an example of an organic EL display device according to an embodiment of the present invention;

FIG. 2 is a diagram schematically showing a cross section taken along line II-II of FIG. 1;

FIG. 3 is a plan view showing an example of a seal material and a filling material disposed on an array substrate;

FIG. 4 is an elevation view of the array substrate shown in FIG. 2 viewed from a side;

FIG. 5 is a sectional view showing an example of a process for bonding the array substrate and a counter substrate together;

FIG. 6 is a plan view showing the seal material and the filling material after bonding of the array substrate and the counter substrate;

FIG. 7 is a sectional view showing the periphery of the seal material after the bonding of the array substrate and the counter substrate; and

FIG. 8 is a plan view showing another example of the filling material disposed on the array substrate.

### DETAILED DESCRIPTION OF THE INVENTION

An embodiment of the present invention is explained below with reference to the drawings. Among components explained in the embodiment, components having the same functions are denoted by the same reference characters and explanation of the components is omitted. To facilitate the explanation, compared with actual forms, forms shown in the drawings are sometimes schematically shown concerning widths, thicknesses, shapes, and the like of portions. However, the forms are only examples and do not limit the interpretation of the present invention.

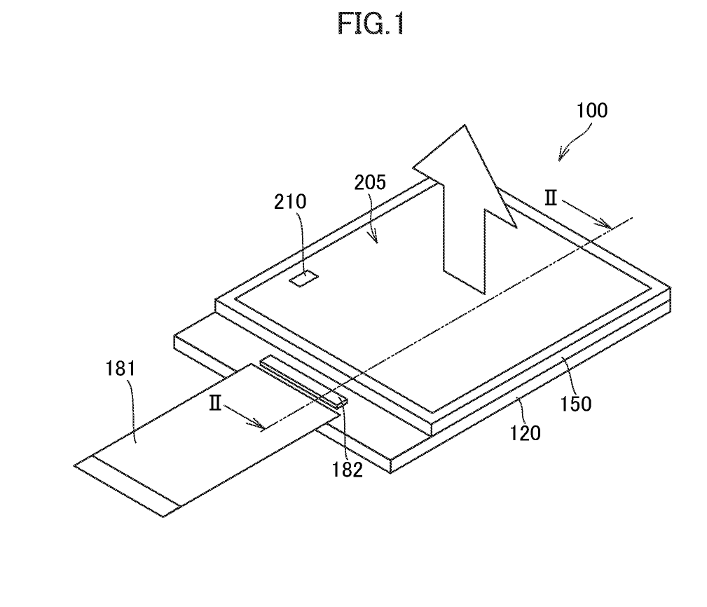

FIG. 1 is a perspective view schematically showing an example of an organic EL display device 100 according to the embodiment of the present invention. As shown in the figure, the organic EL display device 100 includes two substrates, that is, an array substrate 120 and a counter substrate 150. The counter substrate 150 is opposed to the array substrate 120. On the array substrate 120 and the counter substrate 150 of the organic EL display device 100, a display region 205 including pixels 210 arranged in a matrix is formed. Each of the pixels 210 is configured from a plurality of sub-pixels. In this embodiment, the sub-pixels with x columns and y rows are arranged in the display region 205.

The array substrate 120 is a substrate made of, for example, glass or resin. The array substrate 120 includes an insulated surface. Pixel circuits are arranged in a matrix on the array substrate 120. The respective pixel circuits correspond to the sub-pixel and include TFTs (Thin Film Transistors). On the array substrate 120, a drive integrated circuit 182 and a flexible printed circuits board 181 for inputting an image signal and the like from the outside are attached. The drive integrated circuit 182 includes a drive circuit that outputs, to pixel transistors respectively included in the pixel circuits, a scanning signal for causing sources and drains of the pixel transistors to conduct, and the drive circuit outputs potential corresponding to a display tone of the sub-pixels to the sub-pixels. In this embodiment, as indicated by an arrow in the figure, the organic EL display device 100 is an organic EL display device of a top emission type that emits light from a side where a light emitting layer of the array substrate 120 is formed. However, the organic EL display device 100 may be an organic EL display device of a bottom emission type. In this case, the array substrate on the side where the light is emitted needs to have transparency.

On the surface on the array substrate 120 side of the counter substrate 150, for example, a color filter, which transmits lights in respective different wavelength ranges of three colors or four colors, and a black matrix, which is a light blocking film that blocks light leaking from boundaries of the sub-pixels, are formed.

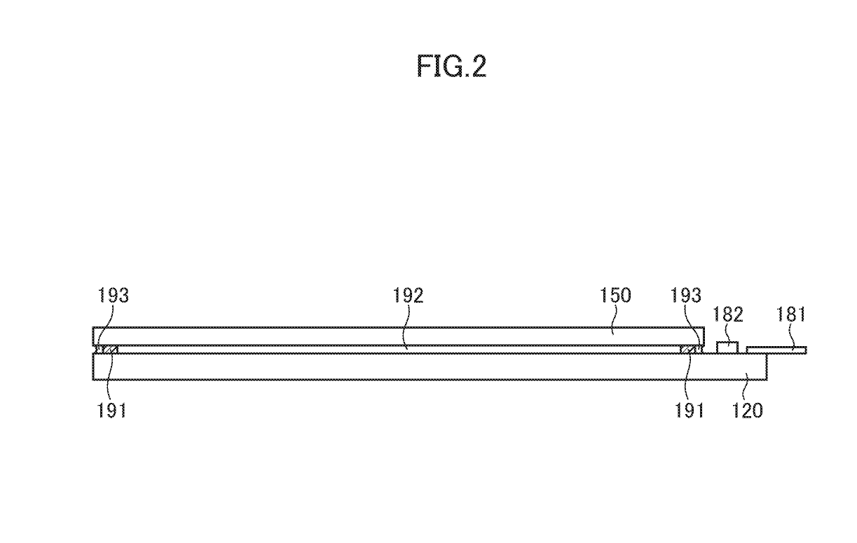

FIG. 2 is a diagram schematically showing a cross section taken along line II-II of FIG. 1. In the figure, the pixel circuits disposed on the surface on the counter substrate 150 side of the array substrate 120, the color filter and the black matrix are omitted. The color filter and the black matrix are disposed on one surface of the counter substrate 150. A filling material 192 between the array substrate 120 and the counter substrate 150 is sealed by a seal material 191. In a region on the outer side of the seal material 191, a leaking portion 193 formed by the filling material leaked to the outside from a region on the inner side of the seal material 191 may be formed.

A manufacturing process for the organic EL display device shown in FIG. 2 is explained.

In a first process, the array substrate 120 provided with the display region 205 for displaying an image is prepared. More specifically, in this process, a pixel circuit, in which light emitting elements equivalent to a plurality of sub-pixels are arranged, is formed on an insulated surface of the array substrate 120 made of an insulating material such as glass or resin. A sealing film for sealing the pixel circuit is formed. Since this process is publicly known, explanation of details of the process is omitted.

In a second process, the counter substrate 150 including a region opposed to the display region 205 is prepared. More specifically, the process includes a process for forming a color filter and a black matrix on the counter substrate 150 made of a transparent insulating material such as glass or resin. Since this process is also publicly known, explanation of details of the process is omitted.

In a third process, the seal material 191 surrounding the display region 205 is applied on the array substrate 120. The seal material 191 is applied so as to seamlessly surround the display region 205. In this process, instead of applying the seal material 191 on the array substrate 120, the seal material 191 surrounding the region opposed to the display region 205 may be applied on the counter substrate 150. The seal material 191 includes a granular filler and transparent or semitransparent resin. The granular filler keeps a clearance between the array substrate 120 and the counter substrate 150 when the array substrate 120 and the counter substrate 150 are bonded together later.

In a fourth process, a filling material 196 is provided in the region surrounded by the seal material 191 on the array substrate 120. The filling material 196 is transparent resin, for example, ultraviolet curing epoxy resin. Note that, when the seal material 191 is provided on the counter substrate 150, the filling material 196 may also be provided on the counter substrate 150.

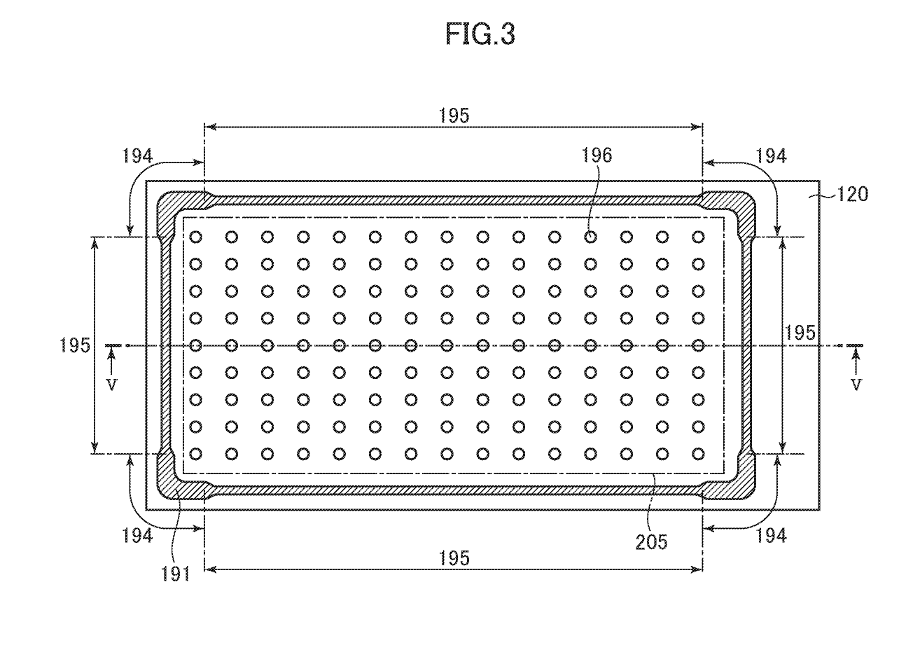

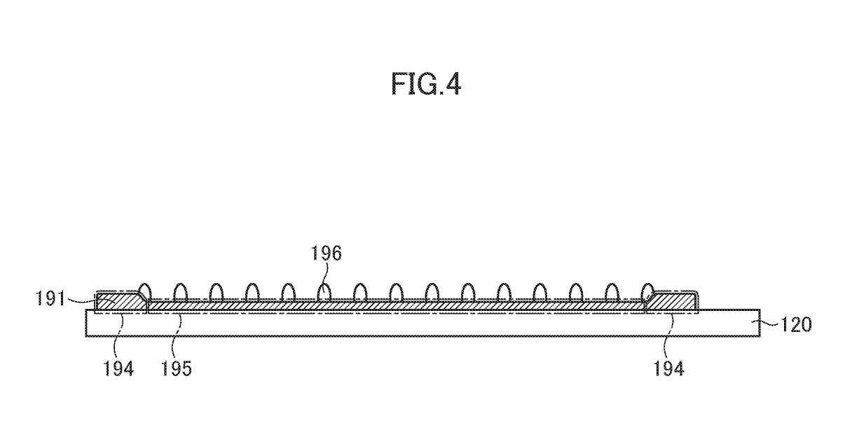

A method of providing the seal material 191 and the filling material 196 in the third process and the fourth process is explained more in detail. FIG. 3 is a plan view showing an example of the seal material 191 and the filling material 196 disposed on the array substrate 120. FIG. 4 is an elevation view of the array substrate 120 shown in FIG. 2 viewed from a side. In FIGS. 3 and 4, the pixel circuit and the like are not shown. In the third process, the seal material 191 is provided to continuously (seamlessly) surround the display region 205 on the inner side of the outer shape of a region where the array substrate 120 and the counter substrate 150 overlap. More specifically, the seal material 191 is provided to extend along the outer shape of the display region 205 having a polygonal shape. When a sectional area in a cross section orthogonal to a direction in which the seal material 191 extends (a length direction) is defined as a seal material sectional area, in the third process, the seal material 191 is provided to include first regions (e.g., corner portions 194) and second regions (e.g., linear portions 195). The second sections have a seal material sectional area smaller than the seal material sectional area of the first regions. More specifically, the first region has the height of the seal material 191 larger than the second regions, or has the width of the seal material 191 larger than the second regions.

In the example shown in FIGS. 3 and 4, the display region 205 is rectangular. The seal material 191 includes the corner portions 194 and the linear portions 195. The corner portions 194 are portions bent along corner portions of the display region 205. The shape of the corner portions 194 is an I shape. The linear portions 195 are linear portions that connect the corner portions 194 adjacent to one another. In the example shown in FIGS. 3 and 4, the corner portions 194 have the seal material sectional area larger than the seal material sectional area of the linear portions 195 and have the height or the width on the array substrate 120 larger than the height or the width of the linear portions 195.

In the third process, regions having the large seal material sectional area in the seal material 191 do not always have to be the corner portions 194. For example, the regions having the large seal material sectional area may be present in the centers among the corner portions 194 adjacent to one another. The seal material sectional area of the linear portions 195 may be larger than the seal material sectional area of the corner portions 194.

In the fourth process, a plurality of droplets of the filling material 196 are provided on the array substrate 120 by dripping of resin droplets. The droplets of the filling material 196 are arranged in a matrix of n rows and m columns (n and m are integers equal to or larger than two). The sizes of the respective droplets of the filling material 196 are the same.

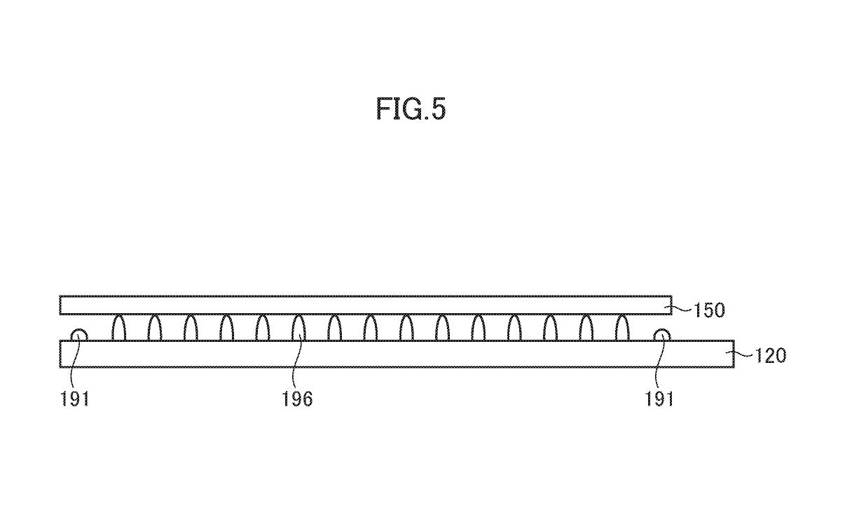

In a fifth process, the array substrate 120 and the counter substrate 150 are bonded together so as to be opposed to each other. FIG. 5 is a sectional view showing an example of a process for bonding the array substrate 120 and the counter substrate 150 together. In the cross section of the figure is a sectional view in a position equivalent to a V-V cut line in FIG. 3. In the fifth process, the array substrate 120 and the counter substrate 150 are disposed such that the seal material 191 and the filling material 196 are present in a region sandwiched by the array substrate 120 and the counter substrate 150. The array substrate 120 and the counter substrate 150 are disposed such that at least a part of the seal material 191 is in contact with the counter substrate 150 and the array substrate 120 under the vacuum.

A sixth process is a process of pressurization by the atmospheric pressure. In this process, the atmospheric pressure is applied to the array substrate 120 and the counter substrate 150 in directions in which the array substrate 120 and the counter substrate 150 come close to each other. A clearance between the substrates corresponds to a size of the filler included in the seal material 191. In this process, the filling material 196 not fit in the region surrounded by the seal material 191 leaks from the linear portions 195.

A seventh process is a process for hardening the filling material 196 and the seal material 191 with ultraviolet ray irradiation. Consequently, bonding of the array substrate 120 and the counter substrate 150 is completed.

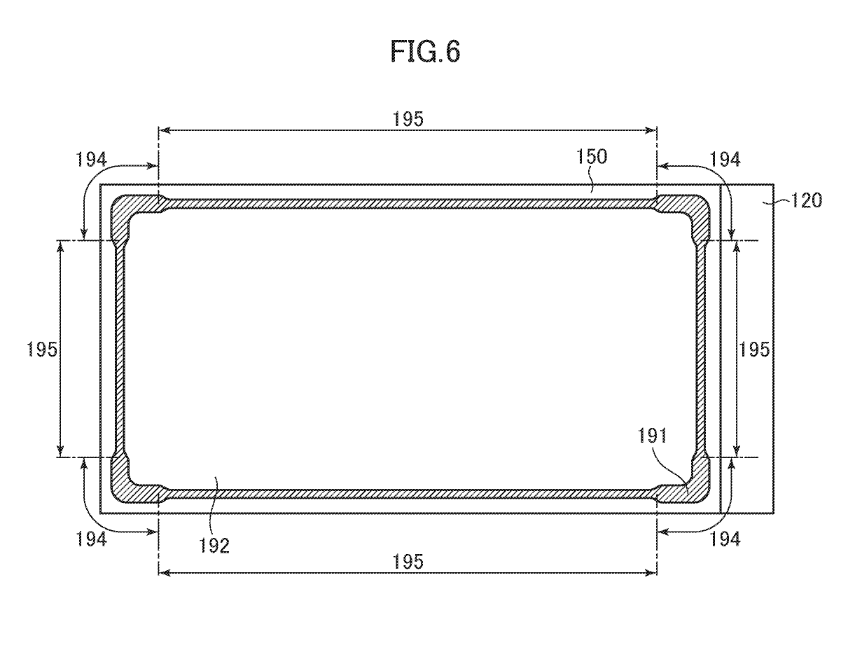

FIG. 6 is a plan view showing the seal material 191 and the filling material 192 after the bonding of the array substrate 120 and the counter substrate 150. The filling material 196 dripped in the fourth process is crushed, fused, and hardened to be the filling material 192 that fills the inner side of the seal material 191. The clearance between the array substrate 120 and the counter substrate 150 is fixed irrespective of a place. When a direction from the array substrate 120 to the counter substrate 150 (a direction between the array substrate 120 and the counter substrate 150) is represented as a height direction, average thickness of the linear portions 195 is slightly smaller than average thickness of the corner portions 194 because the filling material 196 is placed on the seal material 191 when the filling material 196 leaks. On the other hand, the length of the seal material 191 (the width of the seal material 191) in a direction which is orthogonal to the length direction of the seal material 191 and which is extending along the array substrate 120 or the counter substrate 150 is larger in portions corresponding to the first regions in the third process (in the example shown in FIG. 6, the corner portions 194) than in portions corresponding to the second regions in the example shown in FIG. 6, the linear portions 195). It goes without saying that, after the seventh process, the seal material sectional area of the first regions is larger than the seal material sectional area of the second regions.

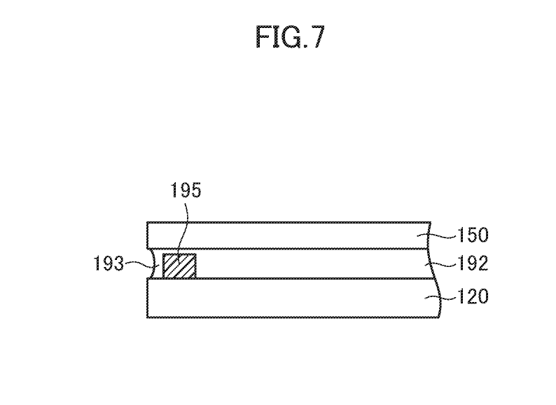

FIG. 7 is a sectional view showing the periphery of the seal material 191 after the bonding of the array substrate 120 and the counter substrate 150. The filling material 196 leaks from the second regions (the linear portions 195) having the small seal material sectional area and thereafter hardened in the fifth or sixth process, whereby the leaking portion 193 is formed in contact with the second region of the seal material 191. In the second region, the filling material 196 is placed on the seal material 191. Note that, in FIG. 7, the linear portion 195 and the counter substrate 150 are not in contact with each other. However, actually, the linear portion 195 and the counter substrate 150 are in contact with each other, for example, around a place where the filler is present.

By varying the seal material sectional area of the seal material 191 in this way, in the fifth process for bonding together the substrates and the sixth process for applying the atmospheric pressure, it is possible to cause the filling material 196 to overflow from the second regions having the small seal material sectional area. As a result, even if there is a excess amount of the filling material 196, it is possible to prevent a bonding failure of the array substrate 120 and the counter substrate 150. It is possible to increase an amount of the filling material 196 disposed in the region surrounded by the seal material 191. It is possible to reduce fluctuation in film thickness in the region between the array substrate 120 and the counter substrate 150 and surrounded by the seal material 191.

In the display device in the past, if an amount of the filling material 196 is too large, a problem occurs in the bonding of the array substrate 120 and the counter substrate 150. On the other hand, since fluctuation in an amount of the filling material 196 is present, an amount of the filling material 196 disposed on the substrates is set slightly smaller than a necessary amount. In this case, the filling material 192 after the bonding of the substrates is insufficient in a frame-like region close to the corners of the display region 205. As a result, even when air bubbles are not formed, a phenomenon occurs in which the film thickness of the filling material 196 is different between the corners of the display region 205 adjacent to the seal material 191 and other places. Unevenness of display occurs.

On the other hand, in the organic EL display device 100 according to this embodiment, a region where an amount of the filling material 192 is insufficient is absent. The film thickness of the filling material 196 is fixed. Consequently, it is possible to reduce the unevenness of display.

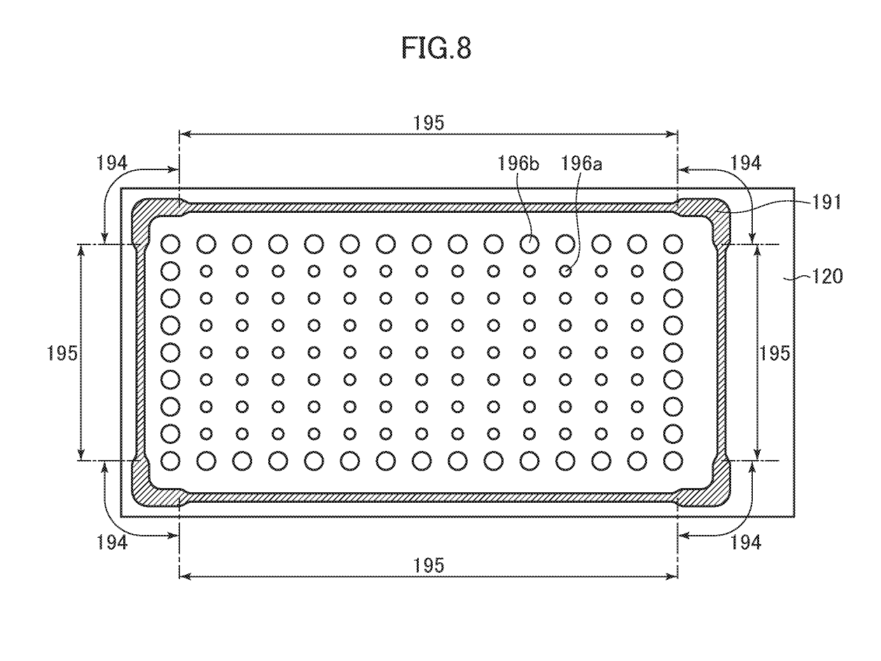

Note that, in the fourth process, the size of the droplets of the filling material 196 may be varied. FIG. 8 is a plan view showing another example of the filling material 196 disposed on the array substrate 120. In the example shown in FIG. 8, in the seal region surrounded by the seal material 191 on the array substrate 120, an amount of the droplets of a filling material 196b disposed in an end portion region adjacent to the seal material 191 is larger than an amount of the droplets of a filling material 196a disposed in a center region present further on the center side than the end portion region. More specifically, the droplets of the filling material 196b adjacent to the seal material 191 are larger than the droplets of the filling material 196a present further on the center side than the adjacent filling material 196b. Consequently, it is possible to more surely prevent the insufficiency of the filling material 192 in the end portion region where the insufficiency of the filling material 192 tends to occur after the substrates are bonded together.

While there have been described what are at present considered to be certain embodiments of the invention, it will be understood that various modifications may be made thereto, and it is intended that the appended claims cover all such modifications as fall within the true spirit and scope of the invention.

What is claimed is:

1. A method for manufacturing a display device comprising:
providing an array substrate on which a display region for an image is provided;
providing a counter substrate to be used and opposed to the array substrate so as to include a region opposed to the display region;
applying a seal material on at least one of the array substrate and the counter substrate to seamlessly surround the display region or the region opposed to the display region;
applying a filling material on a region surrounded by the seal material; and
bonding the array substrate and the counter substrate together via the seal material and the filling material so as to be opposed to each other, wherein
in the applying the seal material, the seal material is provided to include a first region and a second region having a sectional area smaller than a sectional area of the first region in which the sectional area is orthogonal to a length direction of disposition, and
in the bonding the array substrate and the counter substrate together, the filling material is caused to leak to region between the second region of the seal material and at least one of the array substrate and the counter substrate.

2. The method for manufacturing the display device according to claim 1, wherein, in the applying the seal material, the first region of the seal material is applied to be thicker than the second region.

3. The method for manufacturing the display device according to claim 1, wherein, in the applying the seal material, the first region of the seal material is applied to be wider than the second region.

4. The method for manufacturing the display device according to claim 1, wherein
the seal material includes a corner region bent along a shape of the display region, and
the corner region is at least a part of the first region.

5. The method for manufacturing the display device according to claim 1, wherein
in the applying the filling material, the filling material is provided by dripping of droplets, and
the droplets are dripped in a larger amount in an end portion region adjacent to the seal material than in a center region of the region surrounded by the seal material.

6. A display device comprising:
an array substrate on which a display region for an image is provided;
a counter substrate opposed to the array substrate;
a seal material between the array substrate and the counter substrate to seamlessly surround the display region; and
a filling material in a region surrounded by the seal material between the array substrate and the counter substrate, wherein
the seal material includes a first region and a second region having a sectional area smaller than a sectional area of the first region in which the sectional area is orthogonal to a length direction of disposition, and
the filling material leaks to region between the second region of the seal material and at least one of the array substrate and the counter substrate.

7. The display device according to claim 6, wherein the first region of the seal material has width orthogonal to the length direction larger than the width of the second region.

8. The display device according to claim 6, wherein the first region of the seal material has thickness in a direction between the array substrate and the counter substrate larger than the thickness of the second region.

9. The display device according to claim 6, wherein
the seal material includes a corner region bent along a shape of the display region, and
the corner region is at least a part of the first region.
